(19) United States
(12) Patent Application Publication
(10) Pub. No.: US 2021/0157165 A1
(43) Pub. Date: May 27, 2021

(54) DISPLAY PANEL, MANUFACTURING METHOD AND CONTROL METHOD THEREOF, AND DISPLAY DEVICE

(71) Applicants: FUZHOU BOE OPTOELECTRONICS TECHNOLOGY CO., LTD., Fuzhou, Fujian (CN); BOE TECHNOLOGY GROUP CO., LTD., Beijing (CN)

(72) Inventors: Changhong SHI, Beijing (CN); Jin WANG, Beijing (CN); Yao LIU, Beijing (CN); Jiamin LIAO, Beijing (CN); Zongxiang LI, Beijing (CN); Zhendian WU, Beijing (CN); Hao CHENG, Beijing (CN); Zuwen LIU, Beijing (CN)

(21) Appl. No.: 17/043,949

(22) PCT Filed: Feb. 24, 2020
(86) PCT No.: PCT/CN2020/076394

§ 371 Date: Sep. 30, 2020

(30) Foreign Application Priority Data
Apr. 24, 2019 (CN) 201910334149.6

(51) Int. Cl. G02B 30/31; H01L 27/32; G02F 1/1343; G02F 1/1337; G02F 1/1335; G02F 1/1341; G02F 1/137

(52) U.S. Cl. CPC G02B 30/31; H01L 27/3232; G02F 1/134336; G02F 1/13439; G02F 1/133711; G02F 2201/44; G02F 1/133528; G02F 1/1341; G02F 1/137; G02F 2202/28; G02F 1/133504

(57) ABSTRACT

The present disclosure provides a display panel, a manufacturing method and a control method thereof and a display device. The display panel comprises a first substrate and a second substrate disposed opposite to each other, a first electrode layer is disposed on a side of the first substrate proximal to the second substrate, a second electrode layer is disposed on a side of the second substrate proximal to the first substrate, the display panel further comprises a third electrode layer disposed between the first electrode layer and the second electrode layer, a pixel layer disposed between the first electrode layer and the third electrode layer, and a liquid crystal layer disposed between the third electrode layer and the second electrode layer for forming a grating.

### CROSS-REFERENCE TO RELATED APPLICATION

The present application claims the priority of the Chinese Patent Application No. 201910334149.6, filed on Apr. 24, 2019, the disclosure of which is incorporated herein by reference in its entirety.

### TECHNICAL FIELD

The present disclosure relates to the field of display technology, and in particular to a display panel, a manufacturing method and a control method thereof, and a display device.

### BACKGROUND

A naked-eye 3D display device in the related art mainly includes a parallax grating type 3D display device and a prism type 3D display device. The parallax grating type 3D display device generally includes a 2D display panel and a liquid crystal grating panel disposed outside the 2D display panel, and the liquid crystal grating panel is disposed close to a light emission side of the 2D display panel to fit with the 2D display panel. In such a 3D display device with a close-fitting structure, it is difficult to accurately align the liquid crystal grating panel with the display panel and a relative displacement easily appears, such that the parallax barrier and the display panel cannot be accurately matched with each other, resulting in poor light emission uniformity and influencing the 3D display effect. Moreover, such a 3D display device with a close-fitting structure has a large thickness, which does not facilitate realizing a thin display.

### SUMMARY

The present disclosure provides a display panel, a manufacturing method and a control method thereof, and a display device.

The embodiment of the invention provides a display panel, which includes a first substrate and a second substrate disposed opposite to each other, a first electrode layer disposed on a side of the first substrate proximal to the second substrate, and a second electrode layer disposed on a side of the second substrate proximal to the first substrate; wherein the display panel further includes a third electrode layer disposed between the first electrode layer and the second electrode layer, a pixel layer disposed between the first electrode layer and the third electrode layer, and a liquid crystal layer disposed between the third electrode layer and the second electrode layer for forming a grating.

In one embodiment, the third electrode layer includes a plurality of strip-shaped electrodes which are sequentially disposed to have an equal interval between any two adjacent strip-shaped electrodes.

In one embodiment, a material of the third electrode layer includes an opaque conductive material.

In one embodiment, the pixel layer includes a plurality of rows and columns of pixel units, and an extending direction of the plurality of strip-shaped electrode is parallel to a row direction or a column direction of the pixel units.

In one embodiment, an orthographic projection of the plurality of rows and columns of pixel units on the first substrate falls within an orthographic projection of the plurality of strip-shaped electrodes on the first substrate.

In one embodiment, the display panel further includes a transparent adhesive layer disposed on the third electrode layer to fill gaps between the plurality of strip-shaped electrodes.

In one embodiment, the second electrode layer includes a plurality of electrode blocks arranged in an array, multiple electrode blocks of each row are electrically connected to a corresponding row driving line, and multiple electrode blocks of each column are electrically connected to a corresponding column driving line.

In one embodiment, the second electrode layer includes a plurality of electrode blocks arranged in an array, and a plurality of driving lines corresponding to the plurality of electrode blocks arranged in the array one to one and electrically connected to the plurality of electrode blocks arranged in the array, respectively.

In one embodiment, the plurality of electrode blocks arranged in the array correspond to the plurality of rows and columns of pixel units one to one, and an orthographic projection of the plurality of electrode blocks on the first substrate completely overlaps with the orthographic projection of the plurality of rows and columns of pixel units on the first substrate.

In one embodiment, the display panel further includes a first alignment layer on a side of the second electrode layer proximal to the liquid crystal layer, and a second alignment layer on a side of the third electrode layer proximal to the liquid crystal layer, wherein at least one of the first alignment layer and the second alignment layer has a surface grating structure including a plurality of saw-toothed structures, each of the plurality of saw-toothed structures protruding towards the liquid crystal layer.

In one embodiment, each of the plurality of saw-toothed structures forms two faces with respect to a surface at which the saw-toothed structure is located, one face being perpendicular to the surface and the other face being at an acute angle with respect to the surface.

In one embodiment, a material of the surface gate structure includes a photopolymer.

In one embodiment, the pixel layer includes a plurality of organic light emitting diode pixel units, and the third electrode layer further functions as a cathode layer for the pixel layer and a common electrode layer for the liquid crystal layer.

In one embodiment, the pixel layer includes a plurality of liquid crystal pixel units, and the third electrode layer further functions as a pixel electrode layer and a common electrode layer of the liquid crystal layer.

In one embodiment, the display panel further includes a third substrate and a color filter layer corresponding to the plurality of liquid crystal pixel units, the third substrate is disposed between the pixel layer and the third electrode layer; the color filter layer is disposed on a side of the third substrate proximal to the pixel layer.

In one embodiment, the display panel further includes a first polarizer disposed on a side of the second substrate distal to the liquid crystal layer.

In one embodiment, the third electrode layer is a one-piece electrode layer, and the display panel further includes a first polarizer disposed on a side of the second substrate distal to the liquid crystal layer and a second polarizer disposed on a side of the third electrode layer distal to the pixel layer.

The embodiment of the present disclosure further provides a method for manufacturing a display panel, including:

forming a display structure layer and a grating structure layer;

disposing the grating structure layer on a light emission side of the display structure layer; and

forming a liquid crystal layer for forming a grating between the grating structure layer and the display structure layer,

the forming the display structure layer includes:

forming a first electrode layer on a first substrate;

forming a pixel layer on the first electrode layer; and

forming a third electrode layer on the pixel layer,

the forming the grating structure layer includes:

forming a second electrode layer on a second substrate,

the disposing the grating structure layer at the light emission side of the display structure layer includes: disposing the grating structure layer at the light emission side of the display structure layer such that the second electrode layer and the third electrode layer are disposed opposite to each other.

In one embodiment, the forming the third electrode layer on the pixel layer includes forming a plurality of strip-shaped electrodes which are sequentially disposed on the pixel layer to have an equal interval between any two adjacent strip-shaped electrodes.

In one embodiment, the forming the display structure layer further includes:

forming a transparent adhesive layer on the plurality of strip-shaped electrodes;

forming a photopolymer layer on the transparent adhesive layer; and

performing a surface treatment on the photopolymer layer such that a surface grating structure including a plurality of saw-toothed structures are formed on a surface of the photopolymer layer proximal to the liquid crystal layer.

The embodiment of the present disclosure further provides a control method of the display panel as described above, where the control method includes:

in performing a horizontal 3D display, applying a first signal with a constant first voltage value to odd-numbered row electrode blocks, applying a second signal with a constant second voltage value different from the first voltage value to even-numbered row electrode blocks, and applying a signal with the constant second voltage value to the third electrode layer such that the liquid crystal layer forms a horizontal slit grating with bright and dark lines; and

in performing a vertical 3D display, applying the first signal to the odd-numbered column electrode blocks, applying the second signal to the even-numbered column electrode blocks, applying the signal with the constant second voltage value to the third electrode layer such that the liquid crystal layer forms a vertical slit grating with alternate bright and dark lines,

wherein an electric field generated between the first voltage value and the second voltage value causes liquid crystal molecules in the liquid crystal layer to deflect.

The embodiment of the present disclosure further provides a control method of the display panel as described above, the control method includes: applying a third signal and a fourth signal to odd-numbered row electrode blocks and even-numbered row electrode blocks respectively or applying the third signal and the fourth signal to odd-numbered column electrode blocks and even-numbered column electrode blocks respectively to enable the liquid crystal layer to form a slit grating with bright and dark lines with alternate bright and dark lines, which alternates therebetween,

wherein the third signal and the fourth signal each are a rectangular pulse voltage signal, a timing of the third signal and a timing of the fourth signal are opposite to each other, peak values of both the third signal and the fourth signal each are a first voltage value, valley values of both the third signal and the fourth signal each are a second voltage value, and a voltage of a signal applied to the third electrode layer is constant at the second voltage value.

The embodiment of the present disclosure further provides a display device including the display panel described above.

### BRIEF DESCRIPTION OF THE DRAWINGS

The accompanying drawings are used to provide a further understanding of the technical solutions of the present disclosure, are incorporated herein and constitute a part of this specification, are used to explain the technical solutions of the present disclosure together with the embodiments of the present application, and do not limit the technical solutions of the present disclosure.

FIG. 1 is a schematic view of a structure of a display panel according to a first embodiment of the present invention;

FIG. 2 shows a schematic diagram of a structure of a third electrode layer in FIG. 1;

FIG. 3 is a schematic diagram illustrating a principle of modulating light by the third electrode layer shown in FIG. 2;

FIG. 4 is a schematic diagram of an exemplary structure of the second electrode layer in FIG. 1;

FIG. 5a is a schematic diagram illustrating a first signal, a second signal, and a signal applied to a third electrode layer in a control method of a display panel according to an embodiment of the present disclosure;

FIG. 5b is a schematic diagram illustrating a third signal, a fourth signal, and a signal applied to the third electrode layer in a control method of a display panel according to the embodiment of the present disclosure;

FIG. 6a is a flowchart illustrating a control method of a display panel according to an embodiment of the present disclosure;

FIG, 6b is a flowchart illustrating a control method of a display panel according to an embodiment of the present disclosure;

FIG. 7a is a schematic view showing a parallel state of the liquid crystal layer in the absence of an electric field between the third electrode layer and the second electrode layer;

FIG. 7b is a schematic diagram showing a vertical state of the liquid crystal layer in the absence of an electric field between the third electrode layer and the second electrode layer;

FIG. 8 is a schematic diagram of a structure of a display panel according to an embodiment of the present disclosure; and

FIG. 9 is a flowchart of a method for manufacturing a display panel according to an embodiment of the present disclosure.

### DETAILED DESCRIPTION

To make the objects, technical solutions and advantages of the present disclosure more apparent, embodiments of the present disclosure will be described in detail below with reference to the accompanying drawings. It should be noted that, in the present disclosure, the embodiments and the features of the embodiments may be arbitrarily combined with each other without conflict.

The technical contents of the present disclosure will be described in detail through specific embodiments.

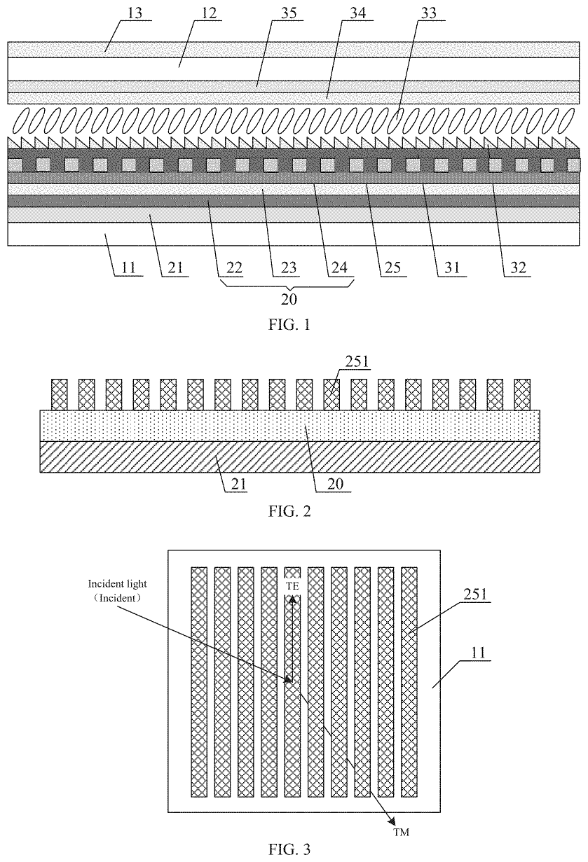

FIG. 1 is a schematic diagram of a structure of a display panel according to an embodiment of the present disclosure. As shown in FIG. 1, the display panel includes a first substrate 11 and a second substrate 12 disposed opposite to each other. A first electrode layer 21 is disposed on a side of the first substrate 11 facing the second substrate 12, a second electrode layer 35 is disposed on a side of the second substrate 12 facing the first substrate 11, and a third electrode layer 25 is disposed between the first electrode layer 21 and the second electrode layer 35. The display panel further includes a pixel layer 20 for displaying an image and a liquid crystal layer 33 for forming a grating. The pixel layer 20 is disposed between the first electrode layer 21 and the third electrode layer 25. and the pixel layer 20 displays an image under the control of the first electrode layer 21 and the third electrode layer 25. The liquid crystal layer 33 is disposed between the third electrode layer 25 and the second electrode layer 35, and the liquid crystal layer 33 forms a liquid crystal grating under the control of the third electrode layer 25 and the second electrode layer 35.

The display panel according to the embodiment of the present disclosure integrates the pixel layer 20 for displaying an image and the liquid crystal layer 33 for forming the liquid crystal grating into one display panel by making the pixel layer 20 and the liquid crystal layer 33 share the third electrode layer 25, and when the liquid crystal layer 33 forms the liquid crystal grating under the control of the third electrode layer 25 and the second electrode layer 35, naked-eye 3D display is realized.

The display panel according to the embodiment of the present disclosure is an integrated 3D display panel, the pixel layer 20 for displaying an image and the liquid crystal layer 33 for forming the liquid crystal grating are integrated into one display panel, so that the precise matching between the liquid crystal grating and the pixel layer can be realized, the relative displacement between the parallax barrier and the pixel layer is avoided, the light emission uniformity of the 3D display panel is improved, and the 3D display effect is improved. Compared with the 3D display panel in the related art, the integrated 3D display panel has the advantages of greatly reducing the thickness, which is beneficial to achieve a thin display.

In order to realize the display function, the second electrode layer 35 is made of a transparent conductive material, such as indium tin oxide and the like.

FIG. 2 shows a schematic diagram of a structure of the third electrode layer in FIG. 1. As shown in FIG. 2, the third electrode layer 25 includes a plurality of strip-shaped electrodes 251 sequentially disposed at an interval, and a material of the strip-shaped electrodes 251 is an opaque conductive material. An extending direction of the plurality of strip-shaped electrodes may be the same as the row or column direction of the plurality of pixel units arranged in an array included in the pixel layer. Further, the orthographic projection of a plurality of rows and columns of pixel units on the first substrate 11 may fall within a range of the orthographic projections of the plurality of strip-shaped electrodes on the first substrate 11, so that the light emission of the pixel layer can be easily controlled. A width of the strip-shaped electrode 251 may be, for example, a width of one pixel unit in the pixel layer, however the present disclosure is not limited thereto. In a specific implementation, the width of the strip-shaped electrode 251 and the gap between two adjacent strip-shaped electrodes 251 may be specifically determined according to actual requirements. A material of the strip-shaped electrode 251 may include one or more metal of platinum (Pt). ruthenium (Ru), gold (Au), silver (Ag), molybdenum (Mo), chromium (Cr), aluminum (Al), tantalum (Ta), titanium (Ti), tungsten (W), and the like. In the third electrode layer 25 with such a structure, the strip-shaped electrodes 251 are opaque, and the gaps between the adjacent strip-shaped electrodes 251 is light transmissive, so that the third electrode layer 25 can form a grating structure to perform a polarization modulation on the light emitted from the pixel layer 20 to the liquid crystal layer 33, and a polarizer is not required to be disposed on a side of the liquid crystal layer 33 proximal to the first substrate 11.

FIG. 3 is a schematic diagram illustrating a principle of modulating light by the third electrode layer. As shown in FIG. 3, the third electrode layer 25 forms a grating structure, a light with a polarization direction parallel to a grating direction (a vertical direction in FIG. 3) cannot pass through, and a light with a polarization direction perpendicular to the grating direction (a horizontal direction in FIG. 3) can pass through, so that the polarization modulation is achieved, The polarized light modulated by the third electrode layer 25 enters the liquid crystal layer 33.

As shown in FIG. 1, the display panel according to the embodiment of the present disclosure further includes a polarizer 13 disposed on a side of the second substrate 12 distal to the liquid crystal layer 33, and the polarizer 13 may be used to modulate the light emitted from the liquid crystal layer 33. Since the third electrode layer 25 can realize the polarization modulation on the light entering the liquid crystal layer 33, a polarizer is not required to be provided on the side of the liquid crystal layer 33 proximal to the first substrate 11, thereby reducing the number of the polarizers used.

Those skilled in the art will understand that the liquid crystal slit grating in the related art can achieve a 3D effect only in one of the horizontal direction or the vertical direction, and cannot achieve a random switching between the horizontal direction and the vertical direction.

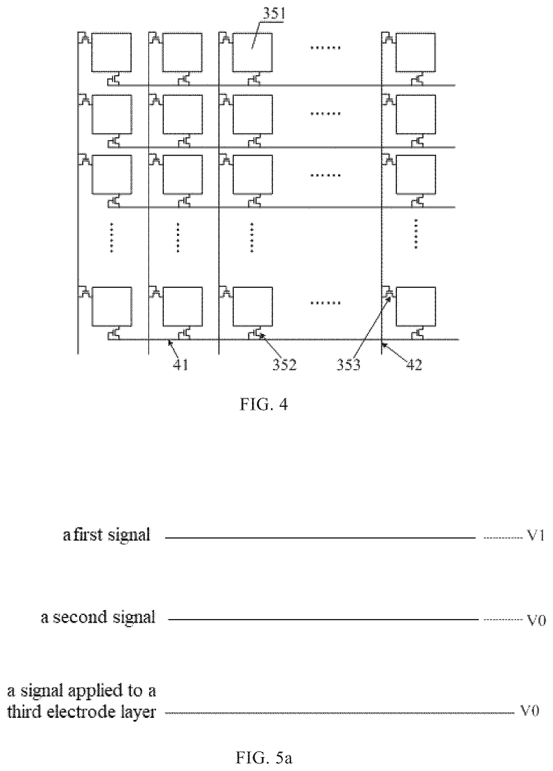

FIG. 4 is a schematic diagram of a structure of the second electrode layer in FIG. In the present embodiment, as shown in FIG. 4, the second electrode layer 35 includes a plurality of electrode blocks 351 arranged in an array. The plurality of electrode blocks 351 of each row are electrically coupled to a row driving line 41 through first control switches 352, respectively, and the plurality of electrode blocks 351 of each column are electrically coupled to a column driving line 42 through second control switches 353, respectively.

With the second electrode layer having such a structure, a horizontal grating or a vertical grating can be easily formed by a signal applied to each row driving line and each column driving line, so that the 3D display effect can be achieved in both the horizontal and vertical directions.

In one embodiment, the plurality of electrode blocks 351 arranged in an array included in the second electrode layer 35 may be individually controlled to achieve a pixel-level control.

In one embodiment of the present disclosure, FIG. 5a is a schematic diagram illustrating a first signal, a second signal and a signal applied to the third electrode layer used in a control method of a display panel according to an embodiment of the present disclosure. The first signal is a signal with a constant voltage value V1, the second signal is a signal with a constant voltage value V0, an electric field generated between the constant voltage value V1 and the constant voltage value V0 can deflect liquid crystal molecules of the liquid crystal layer, and the voltage applied to the third electrode layer is the voltage value V0.

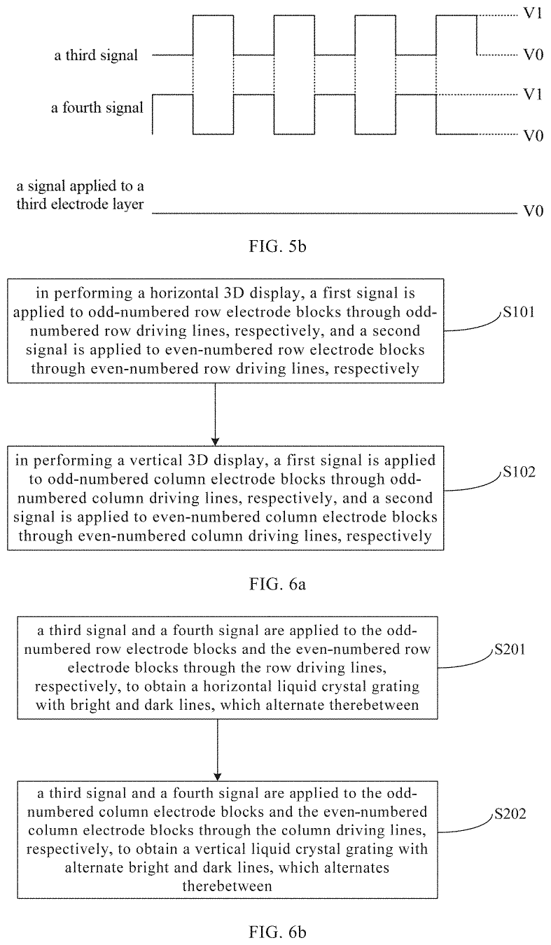

In this case, the control method of the display panel according to the embodiment of the present disclosure, as shown in FIG. 6a, may include:

In S101, in performing a horizontal 3D display, a first signal is applied to odd-numbered row electrode blocks through odd-numbered row driving lines, respectively, and a second signal is applied to even-numbered row electrode blocks through even-numbered row driving lines, respectively. Therefore, a voltage difference V1−V0 between the odd-numbered row electrode blocks and the third electrode layer 25 generates an electric field, so that the liquid crystal molecules in the corresponding odd-numbered row deflect, no light penetrates through the liquid crystal molecules, and the corresponding odd-numbered row is in a dark state; there is no voltage difference between the even-numbered row electrode blocks and the third electrode layer 25 and no electric field is generated, the liquid crystal molecules in the corresponding even-numbered row does not deflect, light passes through, and the corresponding even-numbered row in a bright state, so that a horizontal grating with bright and dark lines is formed, thereby accomplishing a horizontal naked-eye 3D display effect.

In S102, in performing a vertical 3D display, a first signal is applied to odd-numbered column electrode blocks through odd-numbered column driving lines, respectively, and a second signal is applied to even-numbered column electrode blocks through even-numbered column driving lines, respectively. Therefore, the voltage difference V1−V0 between odd-numbered column electrode blocks and the third electrode layer 25 forms an electric field, so that the liquid crystal molecules of the corresponding odd-numbered column deflect, no light penetrates through the liquid crystal molecules, and the corresponding odd-numbered column is in a dark state; there is no voltage difference between the even-numbered column electrode blocks and the third electrode layer 25 and no electric field is generated, the liquid crystal molecules of the corresponding even-numbered column do not deflect, the light passes through, and the corresponding even-numbered column is in a bright state, thereby forming a vertical grating with bright and dark lines, and achieving a vertical naked eye 3D display effect.

The 3D display panel according to the embodiment of the present disclosure may make the liquid crystal molecules of the corresponding row or column in the liquid crystal layer 33 to undergo a row deflection or a column deflection by performing row driving or column driving on the second electrode layer 35, thereby forming a horizontal grating or a vertical grating, and implementing random switching of a 3D display effect in a horizontal direction or a vertical direction.

To implement a pixel-level liquid crystal grating, a size of the electrode block 251 may correspond to a size of one pixel of the pixel layer, for example, a plurality of electrode blocks arranged in an array overlap with the orthographic projection of the pixel units arranged in an array on the first substrate. Therefore, a width of a bright line or a dark line of the formed liquid crystal grating is equivalent to a width of one pixel, so that the bright and dark control of the pixel level is realized, the precision of the liquid crystal grating is improved, and the 3D display effect is improved.

FIG. 5b is a schematic diagram of a third signal, a fourth signal and a signal applied to the third electrode layer used in the control method of the display panel according to the embodiment of the present disclosure. As shown in FIG. 5b, the third signal and the fourth signal each are a rectangular pulse voltage signal, and a timing of the third signal and a timing of the fourth signal are opposite to each other. The peak values of the third signal and the fourth signal are both V1, the valley values of the third signal and the fourth signal are both V0, and the voltage of the signal applied to the third electrode layer is constant at V0.

As shown in FIG. 6b, in S201, in order to obtain a horizontal liquid crystal grating with alternate bright and dark lines, which alternates therebetween, a third signal and a fourth signal are applied to the odd-numbered row electrode blocks and the even-numbered row electrode blocks through the row driving lines, respectively, and then, when a voltage of the third signal applied to the odd-numbered row electrode blocks is V1, a voltage of the fourth signal applied to the even-numbered row electrode blocks is V0; when the voltage of the third signal applied to the odd-numbered row electrode block is V0, the voltage of the fourth signal applied to the even-numbered row electrode block is V1. In this configuration, a liquid crystal grating with alternate bright and dark lines, which alternates therebetween, can be formed in the row direction, which not only can realize the 3D display effect, but also can play a role in peeping prevention.

Similarly, in 202, in order to obtain a vertical liquid crystal grating with alternate bright and dark lines, which alternates therebetween, a third signal and a fourth signal are applied to the odd-numbered column electrode blocks and the even-numbered column electrode blocks through the column driving lines, respectively, and then, when a voltage of the third signal applied to the odd-numbered column electrode blocks is V1, a voltage of the fourth signal applied to the even-numbered column electrode blocks is V0; when the voltage of the third signal applied to the odd-numbered column electrode blocks is V0, the voltage of the fourth signal applied to the even-numbered column electrode blocks is V1. In this configuration, a liquid crystal grating with alternate bright and dark lines, which alternates therebetween, can be formed in the column direction, which not only can realize the 3D display effect, but also can play a role in peeping prevention.

As shown in FIG. 1, the display panel according to the embodiment of the present disclosure further includes a first alignment layer 34 and a second alignment layer 32. The first alignment layer 34 is provided on a side of the second electrode layer 35 proximal to the liquid crystal layer 33, and the second alignment layer 32 is provided on a side of the third electrode layer 25 proximal to the liquid crystal layer 33.

In the present embodiment, as shown in FIG. 1, the second alignment layer 32 is configured as a surface grating structure, and a material of the second alignment layer 32 having the surface grating structure includes photopolymer, In this embodiment, the second alignment layer 32 (i.e. the surface grating structure) is provided on an upper side of the third electrode layer 25 by an adhesive layer 31. A surface of the surface grating structure proximal to the liquid crystal layer 33 is of a saw-toothed shape, and pattern, height, angle and other parameters of the saw-toothed shape may be determined according to specific process conditions and product characteristics. For example, the plurality of saw-toothed structures of the surface grating structure shown in FIG. 1 protrude from the adhesive layer 31 towards the liquid crystal layer 33, and of two faces that each of the saw-toothed structures intersects with the adhesive layer 31, one of the two faces is at a right angle to the adhesive layer 31, and the other face is at an acute angle to the adhesive layer 31.

As shown in FIG. 1. the third electrode layer in the embodiment of the present disclosure is composed of a plurality of strip-shaped electrodes 251, and the gap of the strip-shaped electrodes is filled with the material of the adhesive layer 31 above the strip-shaped electrodes. In this case, the adhesive layer 31 is transparent, so that the opaque strip-shaped electrodes 251 in the third electrode layer can perform the function of a grating polarizer.

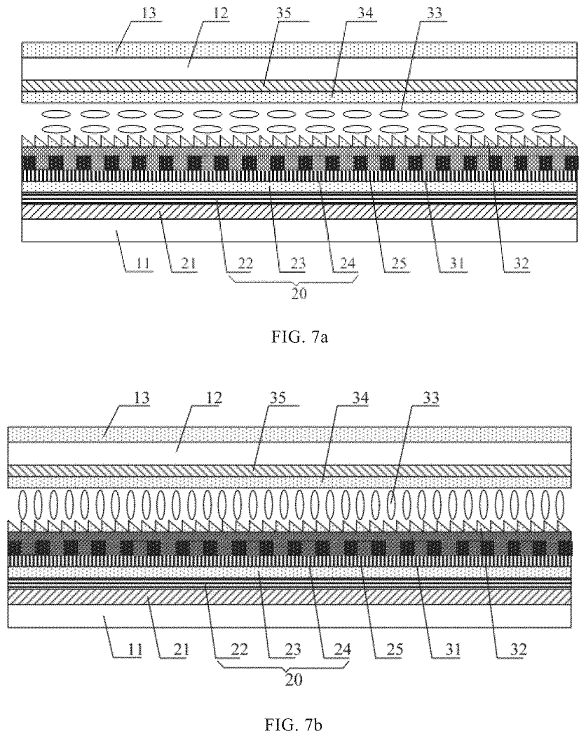

FIG. 7a is a schematic view showing a parallel state of the liquid crystal layer in the absence of an electric field between the third electrode layer and the second electrode layer, and FIG. 7b is a schematic view showing a vertical state of the liquid crystal layer in the absence of an electric field between the third electrode layer and the second electrode layer. The surface grating structure can make the liquid crystal molecules have two kinds of zero-field stable arrangement states of a vertical state and a parallel state without being influenced by heat, pressure and the like. That is, when the voltage between the third electrode layer 25 and the second electrode layer 35 is adjusted to make the liquid crystal molecules in a vertical state, a voltage between the third electrode layer 25 and the second electrode layer 35 is removed, and the liquid crystal molecules can still be kept in the vertical state, as shown in FIG. 7b; when the voltage between the third electrode layer 25 and the second electrode layer 35 is adjusted to make the liquid crystal molecules in a parallel state, the voltage between the third electrode layer 25 and the second electrode layer 35 is removed, and the liquid crystal molecules can still be kept in a parallel state, as shown in FIG. 7a. It is easily understood that, the liquid crystal molecules being in a vertical state refers to a state in which a direction of a long axis of the liquid crystal molecules is perpendicular to the display panel, and the liquid crystal molecules being in a parallel state refers to a state in which the direction of the long axis of the liquid crystal molecules is parallel to the display panel.

Therefore, the second alignment layer 32 is provided as a surface grating structure, and when there is no electric field between the third electrode layer 25 and the second electrode layer 35, the liquid crystal layer can still maintain as a liquid crystal grating, so as to implement a 3D display, thereby reducing a 3D display power consumption of the display panel. Therefore, when the display panel displays a static 3D image, an electric field is not required to be applied between an upper side and a lower side of the liquid crystal layer, and the 3D display power consumption of the display panel is reduced.

It is easily understood that, in one embodiment of the present disclosure, the first alignment layer may be provided as a surface grating structure, and a technical effect of reducing the 3D display power consumption of the display panel may also be achieved.

In the present embodiment, as shown in FIG. 1, the pixel layer 20 may include a plurality of organic light emitting diode (OLED) pixel units, and the pixel layer 20 includes a hole transport layer 22, an organic light emitting layer 23, and an electron transport layer 24 in this order from the first electrode layer 21 to the third electrode layer 25. The first electrode layer 21 serves as an anode layer, the third electrode layer 25 serves as a cathode layer, the third electrode layer 25 simultaneously serves as a common electrode layer for the liquid crystal layer, and the second electrode layer 35 serves as a pixel electrode layer for the liquid crystal layer 33.

In another embodiment, the pixel layer 20 may include a plurality of liquid crystal (LCD) pixel units. At this time, the third electrode layer to which a common electrode signal is applied serves as a common electrode layer, and the first electrode layer and the second electrode layer each serve as a corresponding pixel electrode layer. It is easily understood that, when the pixel layer 20 includes a plurality of liquid crystal pixel units, the display panel may further include a third substrate disposed between the pixel layer 20 and the third electrode layer 25. In order to realize a color display, a color filter layer corresponding to the plurality of liquid crystal pixel units is disposed on a side of the third substrate distal to the pixel layer 20.

FIG. 8 shows a schematic diagram of a structure of a display panel according to an embodiment of the present disclosure. In this embodiment, the third electrode layer as a sharing electrode is a one-piece electrode layer, instead of being formed by a plurality of strip-shaped electrodes arranged at an interval in sequence as shown in FIG. 2, In this case, a second polarizer 43 is provided on a side of the third electrode layer distal to the pixel layer to perform polarization modulation on the light emitted from the pixel layer 20 to the liquid crystal layer 33. The other structures of the display panel shown in FIG. 8 are the same as those shown in FIG. 1, and are not described again.

In the display panel according to the embodiment of the present invention, when a signal with a voltage value of V0 is applied to all the electrode blocks 351 in the second electrode layer 35, that is, when the voltages of the second electrode layer and the third electrode layer are equal, the liquid crystal layer 33 is completely in a bright state, so that the display panel can implement a 2D display. Therefore, the display panel according to the embodiment of the invention can switch between the 3D display and the 2D display by controlling the voltage between the second electrode layer and the third electrode layer.

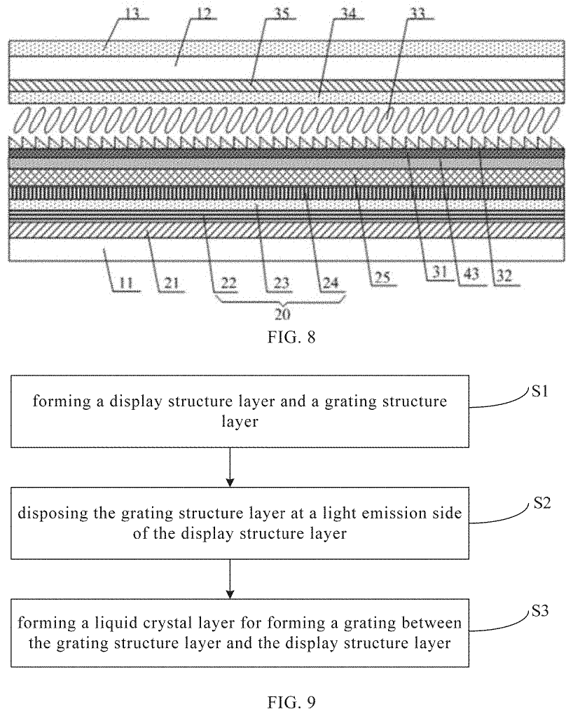

As shown in FIG. 9, another embodiment of the present invention provides a method for manufacturing the display panel shown in FIG. 1, which may include:

S1: forming a display structure layer and a grating structure layer;

S2: disposing the grating structure layer at a light emission side of the display structure layer;

S3: forming a liquid crystal layer for forming a grating between the grating structure layer and the display structure layer, the forming the display structure layer includes:

S111: forming a first electrode layer on a first substrate;

S112: forming a pixel layer on the first electrode layer; and

S113: forming a third electrode layer on the pixel layer.

The forming the grating structure layer includes:

S121: forming a second electrode layer on a second substrate,

S2 specifically includes disposing the grating structure layer at the light emission side of the display structure layer, so that the second electrode layer and the third electrode layer are disposed opposite to each other.

The forming the third electrode layer on the pixel layer includes forming a plurality of strip-shaped electrodes which are sequentially disposed at an equal interval on the pixel layer.

In one embodiment, the forming the display structure layer may further include:

S114: coating a transparent adhesive layer on the plurality of strip-shaped electrodes, wherein in this process, adhesive may also fill gaps between the plurality of strip-shaped electrodes;

S115: forming a photopolymer layer on the adhesive layer; and

S116: performing a surface treatment on the photopolymer layer by a stamping process or an ultraviolet irradiation process to form a surface grating structure on a surface of the photopolymer layer proximal to the liquid crystal layer, that is, the surface of the photopolymer layer proximal to the liquid crystal layer is of a saw-toothed shape, so as to form a second alignment layer.

In one embodiment, the forming the grating structure layer may further include:

S122: forming a first alignment layer on the second electrode layer, wherein a material of the first alignment layer includes polyimide.

Based on the concept of the foregoing embodiments, embodiments of the present disclosure also provide a display device including a display panel employing the foregoing embodiments. The display device may be any product or component with a display function, such as a mobile phone, a tablet computer, a television, a display, a notebook computer, a digital photo frame, a navigator and the like,

In the description of the embodiments of the present disclosure, it is to be understood that, orientations or positional relationships indicated by the terms “middle”, “upper”, “louver”, “front”, “rear”, “vertical”, “horizontal”. “top”, “bottom”, “inner”, “outer”, and the like are based on the orientations or positional relationships shown in the drawings, which is merely for convenience in describing the present disclosure and for simplifying the description, and do not indicate or imply that the device or element referred to must have a particular orientation, be constructed and operated in a particular orientation, and thus, should not be construed as limiting the present disclosure.

In the description of the embodiments of the present disclosure, unless otherwise explicitly stated or limited, it should be noted that the terms “mounted”, “connected”, and “connected” are to be construed broadly and may be, for example, a fixed connection, a detachable connection, or an integral connection; can be mechanically or electrically connected; may be connected directly or indirectly through intervening media, or may be interconnected between two elements. The specific meaning of the above terms in the present disclosure can be understood in a specific case to those of ordinary skill in the art.

Although the embodiments disclosed in the present disclosure are described above, the descriptions are only for the purpose of understanding the present disclosure, and are not intended to limit the present disclosure. It will be understood by those skilled in the art that various changes in form and details may be made therein without departing from the spirit and scope of the present disclosure, and that the scope of the present disclosure is to be limited only by the terms of the appended claims.

1. A display panel, comprising a first substrate and a second substrate disposed opposite to each other, a first electrode layer disposed on a side of the first substrate proximal to the second substrate, and a second electrode layer disposed on a side of the second substrate proximal to the first substrate;
wherein the display panel further comprises a third electrode layer disposed between the first electrode layer and the second electrode layer, a pixel layer disposed between the first electrode layer and the third electrode layer, and a liquid crystal layer disposed between the third electrode layer and the second electrode layer for forming a grating.

2. The display panel according to claim 1, wherein the third electrode layer comprises a plurality of strip-shaped electrodes which are sequentially disposed to have an equal interval between any two adjacent strip-shaped electrodes.

3. The display panel according to claim 2, wherein a material of the third electrode layer comprises an opaque conductive material.

4. The display panel according to claim 3, wherein the pixel layer comprises a plurality of rows and columns of pixel units, and an extending direction of the plurality of stripe-shaped electrodes is parallel to a row direction or a column direction of the pixel units.

5. The display panel according to claim 4, wherein an orthographic projection of the plurality of rows and columns of pixel units on the first substrate falls within an orthographic projection of the plurality of strip-shaped electrodes on the first substrate.

6. The display panel according to claim 5, further comprising a transparent adhesive layer disposed on the third electrode layer to fill gaps between the plurality of stripe-shaped electrodes.

7. The display panel according to claim 6, wherein the second electrode layer comprises a plurality of electrode blocks arranged in an array, multiple electrode blocks of each row are electrically connected to a corresponding row driving line, and multiple electrode blocks of each column are electrically connected to a corresponding column driving line, or
the second electrode layer comprises a plurality of electrode blocks arranged in an array, and a plurality of driving lines corresponding to the plurality of electrode blocks arranged in the array one to one and electrically connected to the plurality of electrode blocks arranged in the array, respectively.

8. (canceled)

9. The display panel according to claim 7, wherein the plurality of electrode blocks arranged in the array correspond to the plurality of rows and columns of pixel units one to one, and an orthographic projection of the plurality of electrode blocks on the first substrate completely overlaps with the orthographic projection of the plurality of rows and columns of pixel units on the first substrate.

10. The display panel according to claim 9, further comprising a first alignment layer on a side of the second electrode layer proximal to the liquid crystal layer, and a second alignment layer on a side of the third electrode layer proximal to the liquid crystal layer, wherein at least one of the first alignment layer and the second alignment layer has a surface grating structure comprising a plurality of saw-toothed structures, and each of the plurality of saw-toothed structures protruding towards the liquid crystal layer.

11. The display panel according to claim 10, wherein each of the plurality of saw-toothed structures forms two faces with respect to a surface at which the saw-toothed structure is located, one face being perpendicular to the surface and the other face being at an acute angle with respect to the surface.

12. The display panel according to claim 11, wherein a material of the surface grating structure comprises photopolymer.

13. The display panel according to claim 12, wherein the pixel layer comprises a plurality of organic light emitting diode pixel units, and the third electrode layer further functions as a cathode layer for the pixel layer and a common electrode layer for the liquid crystal layer.

14. The display panel according to claim 12, wherein the pixel layer comprises a plurality of liquid crystal pixel units, and the third electrode layer further functions as a pixel electrode layer and a common electrode layer for the liquid crystal layer.

15. The display panel according to claim 14, further comprising a third substrate and a color filter layer corresponding to the plurality of liquid crystal pixel units,
wherein the third substrate is disposed between the pixel layer and the third electrode layer; and
the color filter layer is disposed on a side of the third substrate proximal to the pixel layer.

16. The display panel according to claim 15, further comprising a first polarizer on a side of the second substrate distal to the liquid crystal layer.

17. The display panel according to claim 1, wherein the third electrode layer is a one-piece electrode layer, and the display panel further comprises a first polarizer on a side of the second substrate distal to the liquid crystal layer and a second polarizer on a side of the third electrode layer distal to the pixel layer.

18. A method of manufacturing a display panel, comprising:
forming a display structure layer and a grating structure layer;
disposing the grating structure layer at a light emission side of the display structure layer; and
forming a liquid crystal layer between the grating structure layer and the display structure layer for forming a grating,
wherein, the forming the display structure layer comprises:
forming a first electrode layer on a first substrate;
forming a pixel layer on the first electrode layer; and
forming a third electrode layer on the pixel layer, the forming the grating structure layer comprises:
forming a second electrode layer on a second substrate,
the disposing the grating structure layer at the light emission side of the display structure layer comprises: disposing the grating structure layer at the light emission side of the display structure layer such that the second electrode layer and the third electrode layer are disposed opposite to each other.

19. The method according to claim 18, wherein the forming the third electrode layer on the pixel layer comprises forming a plurality of strip-shaped electrodes which are sequentially disposed on the pixel layer to have an equal interval between any two adjacent strip-shaped electrodes.

20. The method according to claim 19, wherein the forming the display structure layer further comprises:
forming a transparent adhesive layer on the plurality of strip-shaped electrodes;
forming a photopolymer layer on the transparent adhesive layer; and
performing a surface treatment on the photopolymer layer such that a surface grating structure comprising a plurality of saw-toothed structures are formed on a surface of the photopolymer layer proximal to the liquid crystal layer.

21. A control method of the display panel according to claim 9, comprising:
in performing a horizontal 3D display, applying a first signal with a constant first voltage value to odd-numbered row electrode blocks, applying a second signal with a constant second voltage value different from the first voltage value to even-numbered row electrode blocks, and applying a signal with the constant second voltage value to the third electrode layer such that the liquid crystal layer forms a horizontal slit grating with bright and dark lines; and
in performing a vertical 3D display, applying the first signal to the odd-numbered column electrode blocks, applying the second signal to the even-numbered column electrode blocks, applying the signal with the constant second voltage value to the third electrode layer such that the liquid crystal layer forms a vertical slit grating with alternate bright and dark lines,
wherein an electric field generated between the first voltage value and the second voltage value causes liquid crystal molecules in the liquid crystal layer to deflect, or comprising:
applying a third signal and a fourth signal to odd-numbered row electrode blocks and even-numbered row electrode blocks respectively or applying the third signal and the fourth signal to odd-numbered column electrode blocks and even-numbered column electrode blocks respectively, and applying a signal to the third electrode layer to enable the liquid crystal layer to form a slit grating with alternate bright and dark lines, which alternates therebetween,
wherein the third signal and the fourth signal each are a rectangular pulse voltage signal, a timing of the third signal and a timing of the fourth signal are opposite to each other, peak values of both the third signal and the fourth signal each are a first voltage value, valley values of both the third signal and the fourth signal each are a second voltage value, and a voltage of a signal applied to the third electrode layer is constant at the second voltage value.

22-23. (canceled)
